(19) United States
(12) Patent Application Publication
(10) Pub. No.: US 2013/0162121 A1
(43) Pub. Date: Jun. 27, 2013

(54) ELECTRONIC DEVICE ENCLOSURE

(71) Applicants: YUN-LUNG CHEN, Tu-Cheng (TW); LIANG-CHIN WANG, Tu-Cheng (TW); YU-MING XIAO, Wuhan City (CN); ZAN LI, Wuhan City (CN); CUI-GUO WANG, Wuhan City (CN)

(72) Inventors: YUN-LUNG CHEN, Tu-Cheng (TW); LIANG-CHIN WANG, Tu-Cheng (TW); YU-MING XIAO, Wuhan City (CN); ZAN LI, Wuhan City (CN); CUI-GUO WANG, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/610,042

(22) Filed: Sep. 11, 2012

(30) Foreign Application Priority Data
Dec. 22, 2011 (CN) 201110434953.5

(51) Int. Cl. H05K 5/03; H05K 7/18

(52) U.S. Cl. 312/223.1

(57) ABSTRACT

An electronic device enclosure includes a side plate and a strengthening plate. The side plate includes a main body, a first mounting flange extending from a first edge of the main body, and a second mounting flange extending from a second edge of the main body. The first mounting flange defines a first clipping hole, and the second mounting flange defines a second clipping hole. The strengthening plate includes a first securing flange and a second securing flange. The first securing flange includes a first clamping portion. The second securing flange includes a second clamping portion. The strengthening plate is moveable in a first direction that is substantially perpendicular to the main body, to engage the first clamping in the first clipping hole; and the strengthening plate is rotatable about an axis, to engage the second clamping portion in the second clipping hole.

### BACKGROUND

1. Technical Field

The present disclosure relates to electronic devices, more particularly to an electronic device enclosure with a strengthening plate.

2. Description of Related Art

Electronic device enclosures, such as a chassis, includes a side plate. To ensure the strength of the side plate, a strengthening panel is attached to an inner surface of the side plate. However, conventional strengthening panel is secured to the side plate by a plurality of screws, that is very inconvenient. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device enclosure in accordance with an embodiment.

FIG. 2 is similar to FIG. 1, but viewed from a different aspect.

FIG. 3 is an assembled view of FIG. 2.

FIG. 4 is similar to FIG. 3, but a strengthening plate is attached to a side plate of the electronic device of FIG. 2.

FIG. 5 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

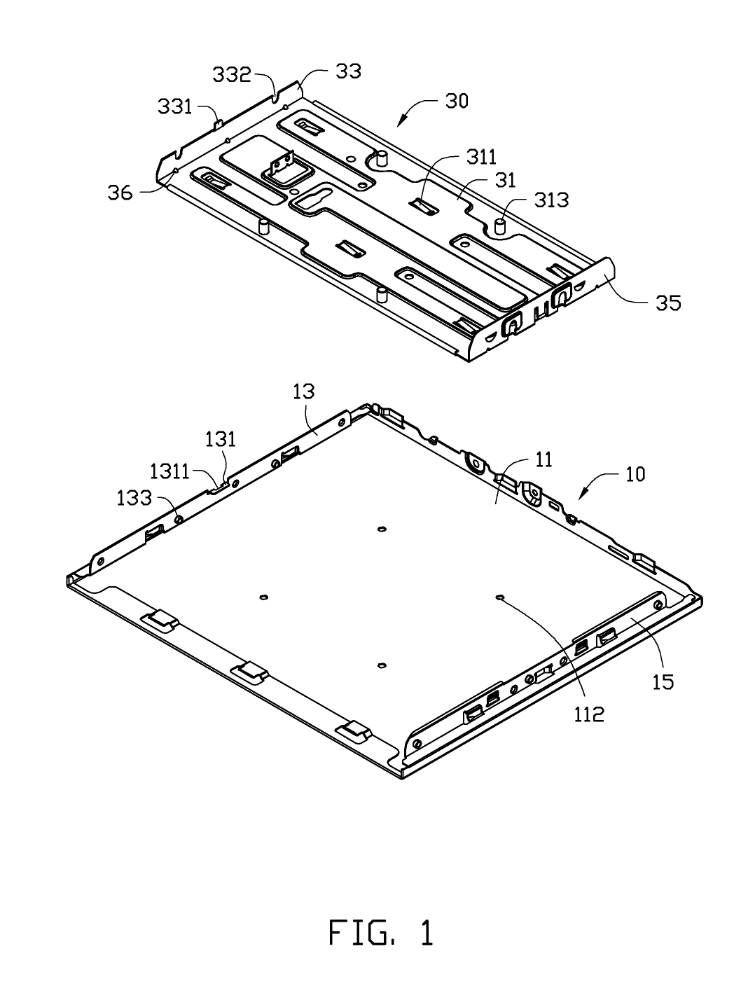

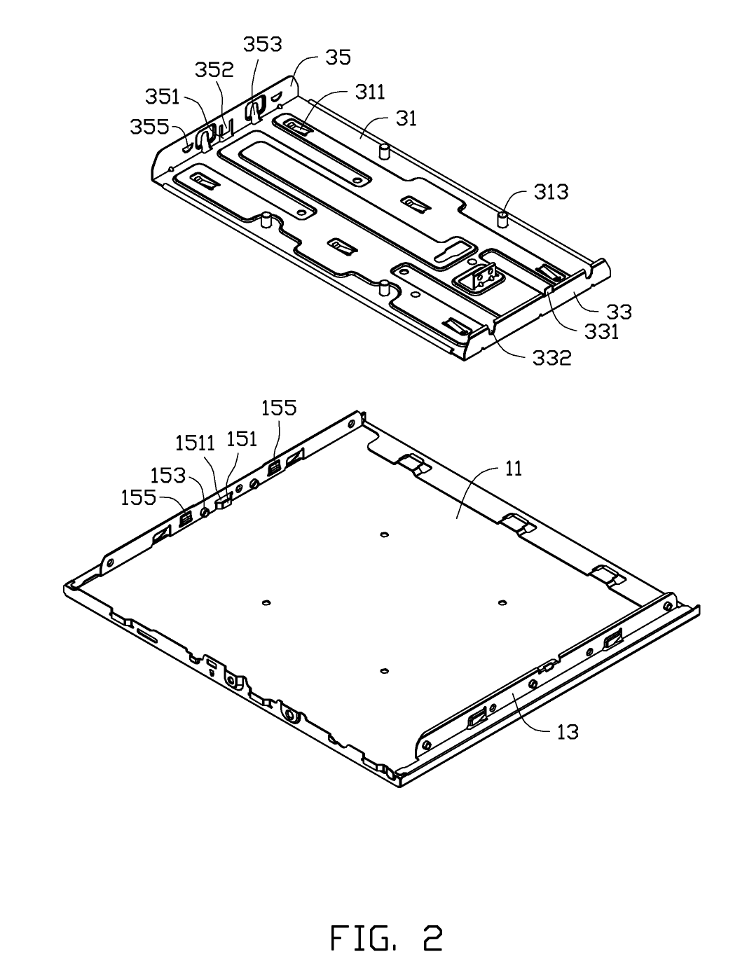

Referring to FIGS. 1-3, an electronic device enclosure in accordance with an embodiment is shown. The electronic device enclosure includes a side plate 10 and a strengthening plate 30 attached to the side plate 10. In one embodiment, the side plate 10 is a side plate of a personal computer case.

The side plate 10 includes a main body 11, a first mounting flange 13 extending from a first edge of the main body 11, and a second mounting flange 15 extending from a second opposite edge of the main body 11. In one embodiment, the first mounting flange 13 is substantially parallel to the second mounting flange 15 and substantially perpendicular to the main body 11.

The main body 11 defines four positioning holes 112. A clipping portion 131, with a first clipping hole 1311, is located on the first mounting flange 13. The clipping portion 131 extends towards the interior of the main body 11. Two securing posts 133 are located on opposite sides of the clipping portion 131 of the first mounting flange 13. The second mounting flange 15 includes a bridge 151, two mounting posts 153, and two resisting portions 155. The two mounting posts 153 are located on opposite sides of the bridge 151, and each of the two resisting portions 155 is adjacent to each of the two mounting posts 153. A second clipping hole 1511 is defined between the bridge 151 and the second mounting flange 15.

The strengthening plate 30 includes a strengthening main body 31, a first securing flange 33 extending from a first edge of the strengthening main body 31, and a second securing flange 35 extending from a second opposite edge of the strengthening main body 31. In one embodiment, the first securing flange 33 is substantially parallel to the second securing flange 35 and substantially perpendicular to the strengthening main body 31.

The strengthening main body 31 includes a plurality of elastic pieces 311, and four positioning posts 313, corresponding to the four positioning holes 112. The four positioning posts 313 are located on the strengthening main body 31. Each of the plurality of elastic pieces 311 is set an angle relative to the strengthening main body 31. In one embodiment, each of the four positioning posts 313 may define a through hole (not shown), and a mounting member, such as a screw, can be engaged in the through hole and the positioning hole 112, to secure an electronic component to the side plate 10. The electronic component can be an audio component. A first clamping portion 331 extends upward from the first securing flange 33. Two cutouts 332, located on opposite side of the first clamping portion 331, are defined in the first securing flange 33. The second securing flange 35 defines an opening 351, and a second clamping portion 352 extends from an edge of the second securing flange 35. In one embodiment, the second clamping portion 352 is a piece, and the second clamping portion 352 and the second securing flange 35 are located on the same plane. Two sliding slots 353 are defined in the second securing flange 35 and located on opposite sides of the second clamping portion 352. Two protruding portions 355 are located on the second securing flange 35, and each of the two protruding portions 355 is adjacent to each of the sliding slots 353. In one embodiment, each of the sliding slots 353 is L-shaped and includes a bottom end and a top end, opposite to the bottom end. A plurality of strengthening ribs 36 are located on a connecting portion that is connected to the strengthening main body 31 and the first securing flange 33, or it is located on a connecting portion that is connected to the strengthening main body 31 and the second securing flange 35.

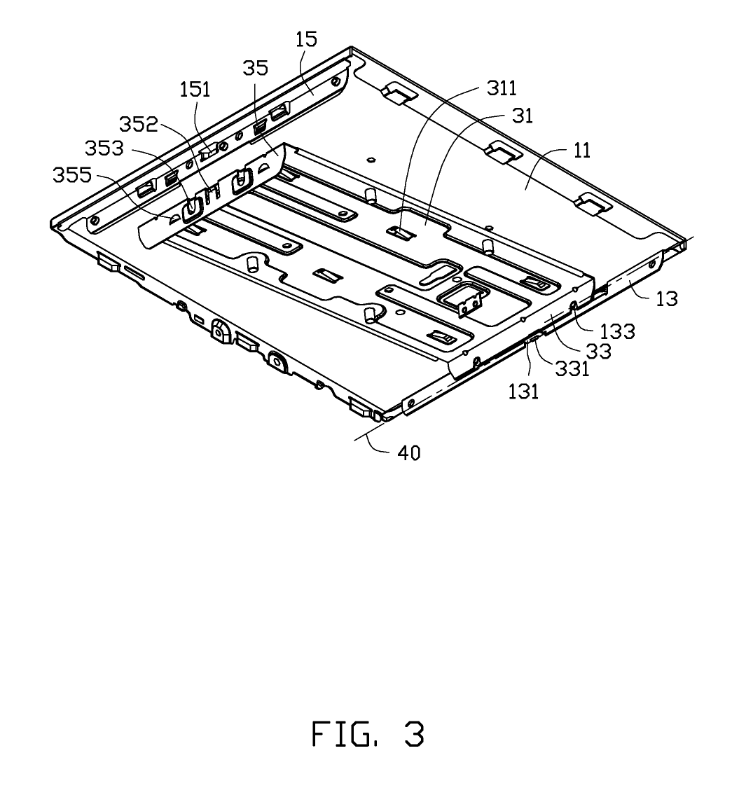

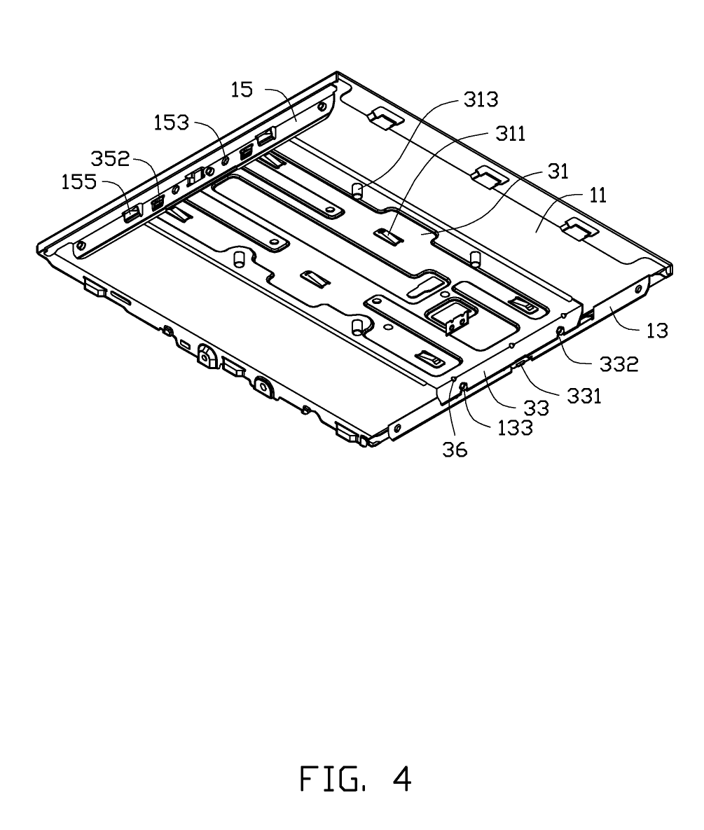

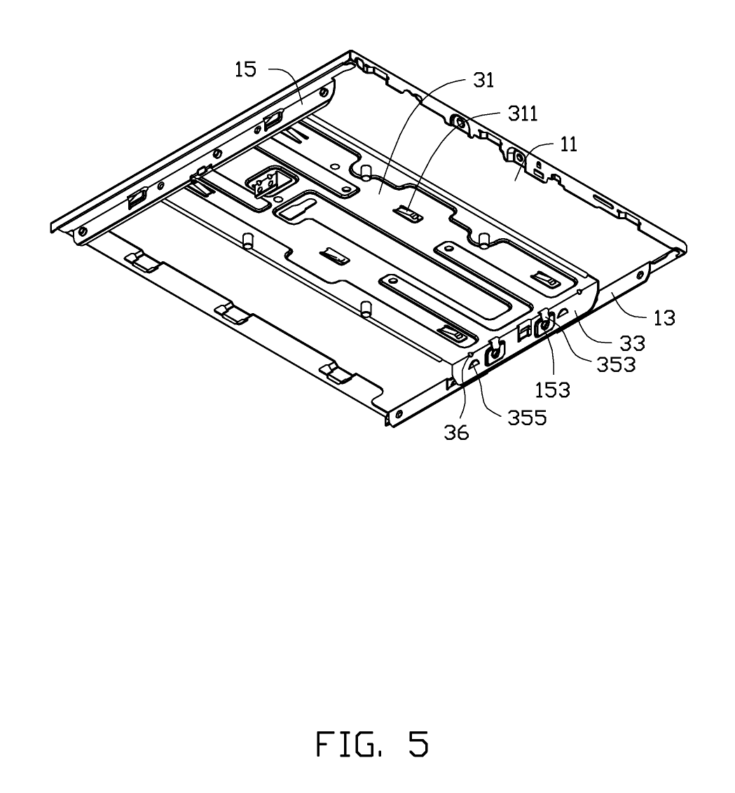

Referring to FIGS. 3-5, in assembly, the strengthening plate 30 abuts the inner surface of the side plate 10. The first clamping portion 331 is aligned with the first clipping hole 1311. The strengthening plate 30 is moved in a first direction substantially perpendicular to the main body 11, to engage the first clamping portion 331 in the first clipping hole 1311. The two securing posts 133 are engaged in the two cutouts 332. At this position, see FIG. 3, the strengthening plate 30 is slanted relative to the main body 11. The strengthen plate 30 is rotated about an axis 40, until the second clamping portion 352 is engaged in the second clipping hole 1511. The two mounting posts 153 are received in the two sliding slots 353. The protruding portion 355 abuts the resisting portion 155, the plurality of elastic pieces 311 abuts the main body 11, and each of the plurality of positioning posts 313 is aligned with each of the plurality of positioning holes 112.

In disassembly, the strengthening plate 30 is moved in the first direction, and the second clamping portion 352 is removed from the second clipping hole 1511. Each of the two mounting posts 153 is slid to the bottom end of each of the sliding slots 353. The strengthening plate 30 is rotated about the axis 40, to disengage each of the two mounting posts 153 from each of the sliding slots 353. The first clamping portion 331 is disengaged from the first clipping hole, and the two securing posts 133 are detached from the two cutouts 332. Thus, the strengthening plate 30 can be disengaged from the side plate 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure comprising:
a side plate comprising a main body, a first mounting flange extending from a first edge of the main body, and a second mounting flange extending from a second edge of the main body; the first mounting flange defines a first clipping hole, and the second mounting flange defines a second clipping hole; and
a strengthening plate comprising a first securing flange and a second securing flange; the first securing flange comprises a first clamping portion; and the second securing flange comprises a second clamping portion;
wherein the strengthening plate is moveable in a first direction that is substantially perpendicular to the main body, to engage the first clamping in the first clipping hole; and the strengthening plate is rotatable about an axis, to engage the second clamping portion in the second clipping hole.

2. The electronic device enclosure of claim 1, wherein the strengthening plate further comprises a strengthening main body connected to the first securing flange and the second securing flange, the strengthening main body comprises a plurality of elastic pieces, and the plurality of elastic pieces abut the main body of the side plate.

3. The electronic device enclosure of claim 2, wherein the main body of the side plate defines a positioning hole, and the strengthening main body comprises a positioning post engagable in the positioning hole.

4. The electronic device enclosure of claim 2, wherein the strengthening plate further comprises a plurality of strengthening ribs, and the plurality of strengthening ribs are locatable between the first securing flange and the strengthening main body.

5. The electronic device enclosure of claim 1, wherein the first mounting flange defines a cutout adjacent to the first clipping hole, the first securing flange comprises a securing post, and the securing post is receivable in the cutout.

6. The electronic device enclosure of claim 1, wherein a clipping portion extends from a top edge of the first mounting flange towards an inside of the main body, and the first clipping hole is defined in the clipping portion.

7. The electronic device enclosure of claim 1, wherein the second securing flange defines a sliding slot, and the second mounting flange further comprises a mounting post slidably received in the sliding slot.

8. The electronic device enclosure of claim 1, wherein the second securing flange further comprising a protruding portion, and the second mounting flange further comprises a resisting portion abutting the protruding portion.

9. An electronic device enclosure comprising:
a side plate comprising a first mounting flange and a second mounting flange, substantially parallel to the first mounting flange; the first mounting flange comprises a clipping portion extending from the first mounting flange; the clipping portion defines a first clipping hole, and the second mounting flange defines a second clipping hole; and
a strengthening plate comprising a first securing flange and a second securing flange; the first securing flange comprises a first clamping portion; and the second securing flange comprising a second clamping portion;
wherein the strengthening plate is moveable in a first direction that is substantially perpendicular to the side plate, so that the first clamping is engaged in the first clipping hole; the strengthening plate is rotatable about a shaft substantially parallel to the first mounting flange, so that the second clamping portion is moveable in a second direction opposite to the first direction to engage in the second clipping hole.

10. The electronic device enclosure of claim 9, wherein the side plate comprises a main body, the strengthening plate further comprises a strengthening main body connected to the first securing flange and the second securing flange, the strengthening main body comprising a plurality of elastic pieces, and the plurality of elastic pieces abut the main body.

11. The electronic device enclosure of claim 10, wherein the main body defines a positioning hole, and the strengthening main body comprises a positioning post engagable in the positioning hole.

12. The electronic device enclosure of claim 10, wherein the strengthening plate comprises a plurality of strengthening ribs, and the plurality of strengthening ribs are locatable between the first securing flange and the strengthening main body.

13. The electronic device enclosure of claim 9, wherein the first mounting flange defines a cutout adjacent to the first clipping hole, the first securing flange comprises a securing post, and the securing post is receivable in the cutout.

14. The electronic device enclosure of claim 9, wherein the second securing flange defines a sliding slot, and the second mounting flange comprises a mounting post slidably receivable in the sliding slot.

15. The electronic device enclosure of claim 9, wherein the second securing flange comprising a protruding portion, and the second mounting flange comprises a resisting portion abutting the protruding portion.
